(19) United States
(12) Patent Application Publication
(10) Pub. No.: US 2009/0251964 A1
(43) Pub. Date: Oct. 8, 2009

(54) NONVOLATILE SEMICONDUCTOR MEMORY DEVICE

(75) Inventors: Yoshitaka Sasago, Tachikawa (JP); Hitoshi Kume, Musashino (JP)

Correspondence Address: MILES & STOCKBRIDGE PC, 1751 PINNACLE DRIVE, SUITE 500, MCLEAN, VA, 22102-3833, US

(73) Assignee: HITACHI, LTD.

(21) Appl. No.: 12/414,654

(22) Filed: Mar. 30, 2009

(30) Foreign Application Priority Data
Apr. 7, 2008 (JP) JP 2008-99104

(51) Int. Cl. G11C 16/02; G11C 16/06

(52) U.S. Cl. 365/185.05; 365/185.18

(57) ABSTRACT

A nonvolatile semiconductor memory device according to the present invention is a NAND-type flash memory which is electrically capable of programming/erasing. The nonvolatile semiconductor memory device has at least 3 or more memory cell columns in which a plurality of memory cells are connected in series, and these memory cell columns are adjacent to each other via a shallow trench isolation. And, a programming operation is performed individually to each of these memory cell columns. In this manner, a programming-prevent voltage is surely provided at on at least one side of both surfaces of the semiconductor substrate which are adjacent via a shallow trench isolation to the surface of the semiconductor substrate under the programming-prevented memory cell. Therefore, a miss-programming to an unselected memory cell can be largely reduced.

### CROSS-REFERENCE TO RELATED APPLICATION

The present application claims priority from Japanese Patent Application No. 2008-99104 filed on Apr. 7, 2008, the content of which is hereby incorporated by reference into this application.

### TECHNICAL FIELD OF THE INVENTION

The present invention relates to a nonvolatile semiconductor memory device. More particularly, the present invention relates to a technique to realize high integration and high performance of a nonvolatile semiconductor memory device which is electrically capable of programming/erasing.

### BACKGROUND OF THE INVENTION

As a technique which the inventors have studied, for example, the following techniques are considered in a nonvolatile semiconductor memory device.

Among nonvolatile semiconductor memory devices which are electrically capable of programming/erasing, so-called flash memory is known as the one which is capable of bulk erasing. Since the flash memory is excellent in portability and impact resistance and capable of electrically bulk erasing, a demand of the flash memory has been rapidly expanded in recent years as a memory device of a personal digital assistant such as a mobile personal computer and a digital still camera. It is an important factor to reduce a bit-cost by scaling down of an area size of a memory cell for the expansion of the market, and various memory-cell methods are suggested for realizing such reduction.

For example, Non-Patent Document 1 (International Electron Devices Meeting, 2004, IEEE, p. 873-876), Non-Patent Document 2 (Solid-State Circuits Conference, 2005, IEEE, p. 44-45), Non-Patent Document 3 (Solid-State Circuits Conference, 2005, IEEE, p. 46-47), and Non-Patent Document 4 (International Electron Devices Meeting, 2007, IEEE, p. 445-448) report an example of so-called NAND-type flash memory which is one type of a contact-less type cell which is appropriate for large volume. It has been succeeded to reduce a physical area size of the memory cell up to almost 4F² (F: minimum feature size) by using this configuration, and besides, it has been realized to achieve the large volume by combining with a so-called multilevel technique in which information of 2 bit or more is recorded into one cell.

A distance between memory cells is closer as a reduction of memory cell size of the NAND-type flash memory proceeds, and therefore, there has arisen a problem of a threshold voltage shift by a capacitive coupling between memory cells (Non-Patent Document 5: International Electron Devices Meeting, 2007, IEEE, p. 27-30). To reduce the threshold voltage shift is an essential issue for ensuring reliability of the NAND-type flash memory, and more particularly, for advancing the large volume by a micro-fabrication multilevel technique. In a device technique, there are reported a method in which the threshold voltage shift is reduced by lowering a height of a floating gate and reducing a facing area size between the adjacent floating gates (Non-Patent Document 4), and a method in which the threshold voltage shift is reduced by using a memory cell of a discrete-trap type instead of the floating gate (Non-Patent Document 5). For example, as seen in Non-Patent Document 6 (Symp. on VLSI circuit Dig. Pp., 2007, IEEE, p. 188-189) and 7 (Symp. on VLSI circuit Dig. Pp., 2007, IEEE, p. 190-191), and in Patent Document 1 (U.S. Patent Application Publication No. 2007/0159881), 2 (Japanese Patent Application Laid-open Publication No. 2007-18708), 3 (U.S. Patent Application Publication No. 2007/0121378), and 4 (Japanese Patent Application Laid-open Publication No. 2004-192789), also in an operation technique, there are suggested some of techniques in which the threshold voltage shift by the adjacent memory cells is reduced as much as possible.

### SUMMARY OF THE INVENTION

By the way, the inventors have studied about the technique of the nonvolatile semiconductor memory device as described above, and as a result, the followings have been found.

For example, a defect by the capacitive coupling with the reduction of memory cell size of the NAND-type flash memory occurs not only between the floating gates. A capacitive coupling also increases between surfaces of a semiconductor substrate under cell transistors which are adjacent to each other in a word line direction. Therefore, in a programming operation of the NAND-type flash memory, a miss-programming increases on a memory cell, to which the programming is not performed, under the selected word line. This becomes a cause to reduce the reliability of the NAND-type flash memory as well as the above-described threshold voltage shift by the capacitive coupling between the floating gates.

For explaining the issue easier, a device structure and a programming operation of the NAND-type flash memory will be described.

FIG. 1 is a planer diagram showing one part of a memory cell array of the NAND-type flash memory, and FIG. 2, FIG. 3A, and FIG. 3B are cross section diagrams on A-A line, B-B line, and C-C line in FIG. 1, respectively. Note that, in the planer diagram of FIG. 1, one part of materials is omitted for showing Figures easier.

As shown in FIG. 1 to FIG. 3, the memory cell has: a p-type well which is formed on a main surface of a p-type semiconductor substrate 1; a floating gate 5; and control gates 7 and 8. Control gates 7 and 8 in each memory cell are connected in a row direction (x direction) to form a word line WL. The floating gate 5 and the p-type well 10 are isolated by a gate insulator 4, and the floating gate 5 and the word line WL are isolated by a second insulator 6.

Each memory cell is connected in series in a column direction (y direction) on an active region which is element-isolated to each other to form a bit line BL. Each end of the memory cell is connected to an n-type diffusion layer (BLDL) 11 which is connected to a bit line contact via select transistors (ST-Tr1 and ST-Tr2), and to an n-type diffusion layer (CSDL) 12 which forms a common source line.

FIG. 4 is a schematic diagram of a circuit diagram of the memory cell array of the NAND-type flash memory. FIG. 4 is an example of a reading of “B” page.

In the reading, as shown in FIG. 4, 1 V is applied to the bit line BL which is connected to a selected memory cell SMC and other memory cells via the select transistor ST-Tr 1, about 5 V is applied to the select transistors ST-Tr 1 and ST-Tr 2, about 5 V is applied to an unselected word line USWL, 0 V is applied to the common source line CS, and 0 V is applied to the p-type well 10. Further, a reading determination voltage Vread is applied to the selected word line SWL to determine ON/OFF of the selected memory cell SMC. Normally, as shown in FIG. 4, this operation is performed individually to each of two pages (A page and B page) obtained by making groups so as to divide bit lines into each bit line.

The programming in the NAND-type flash memory is performed by using Fowler-Nordheim tunnel current via a tunnel insulator.

FIG. 5 is a circuit diagram describing a voltage condition in the programming to B page. In FIG. 5, an example of the voltage condition in the programming of B page is shown.

The programming is performed to a memory cell which is connected to the selected word line SWL. Although there are cases that the programming is performed and not performed even to each of the memory cells which are connected to the same selected word line SWL, this is controlled by a potential of the bit line BL. About 2 V is applied to the select transistor ST-Tr1, 0 V is applied to bit lines BL₂ₙ₋₂ and BL₂ₙ which perform the programming to the selected memory cell SMC under the selected word line SWL, about 3 V is applied to bit lines BL₂ₙ₋₁ and BL₂ₙ₊₁ which do not perform the programming. The common source line CS, the select transistor ST-Tr2, and the p-type well are at 0 V. With this state, the potential of the unselected word line USWL is rapidly increased from 0 V to about 10 V (about several micro seconds or less). Accordingly, a potential of the floating gate under the unselected word line USWL is increased, and by an influence of the potential, a potential of a surface of the semiconductor substrate under the memory cell also tends to increase.

Since the select transistor ST-Tr1 becomes OFF state in the bit lines BL₂ₙ₋₁ and BL₂ₙ₊₁ whose bit line potentials are set to about 3 V, the surface potential of the substrate under the memory cell is increased to be “VH”. On the other hand, since the select transistor ST-Tr1 becomes ON state in the bit lines BL₂ₙ₋₂ and BL₂ₙ whose bit line potentials are set to 0 V, electron is supplied from the bit line contact to the surface of the substrate under the memory cell, so that the potential becomes 0 V.

Next, the potential of the selected word line SWL is increased from 0 V to about 20 V. At this time, in bit lines BL₂ₙ₋₂ and BL₂ₙ in which the potential of the surface of the substrate is at 0 V, a large potential difference occurs between the floating gate and the surface of the substrate, so that electron is injected from the surface of the substrate to the floating gate by the tunnel current, thereby causing the programming. On the other hand, in bit lines BL₂ₙ₋₁ and BL₂ₙ₊₁ in which the potential of the surface of the substrate is at VH, the potential difference between the floating gate and the surface of the substrate is relaxed, thereby not causing the programming.

FIG. 6 is a schematic diagram of a circuit diagram of the memory cell array of the NAND-type flash memory, and shows an example of the voltage condition in the erasing.

FIGS. 7A and 7B show an electron transfer between the surface of the substrate under the memory cell and a diffusion layer on the bit line contact side via the select transistor ST-Tr1. A case of programming is shown in FIG. 7A, and a case of not programming is shown in FIG. 7B.

FIG. 8 shows a surface of a silicon substrate in a case that the programming is not performed to the unselected memory cell USMC (the case of FIG. 7B), a surface of a silicon substrate under the memory cell which is adjacent in the floating gate and word line direction, and a relation of the capacitive coupling to the silicon substrate. FIG. 8A shows the voltage condition of a case that the programming is performed to a cell which is adjacent to the unselected memory cell USMC in the word line direction, and FIG. 8B shows the voltage condition of a case that the programming is not performed to a cell which is adjacent to the unselected memory cell USMC in the word line direction.

FIG. 9 shows a surface of a silicon substrate in a case that the programming is not performed to the unselected memory cell USMC (the case of FIG. 7B), a surface of a silicon substrate under the memory cell which is adjacent in the floating gate and word line direction, and a relation of the capacitive coupling to the silicon substrate. FIG. 9A shows the voltage condition of a case that the programming is performed to a memory cell (right side) which is adjacent to the unselected memory cell USMC in the word line direction, and FIG. 9B shows the voltage condition of a case that the programming is performed to a memory cell (left side) which is adjacent to the unselected memory cell USMC in the word line direction.

FIG. 10 is a timing diagram of a programming sequence.

By rapidly increasing the unselected word line USWL from 0 V to 10 V, the potential of the floating gate also increases with a degree of ΔVfg. The potential VH of the surface of the substrate is indicated by multiplication of ΔVfg and a coupling ratio Cox/(Cox+Cdep) which is determined by a tunnel insulator capacitance Cox and a depletion layer capacitance Cdep.

VH=ΔVfg×Cox/(Cox+Cdep) (1)

Since such a programming is individually performed to each of the above-described A and B two pages in a conventional NAND-type flash memory, all of B pages become a programming-prevent cell in the programming to A pages. However, due to increasing of the capacitive coupling between channels which are adjacent to each other via the shallow trench isolation in the surface of the semiconductor substrate as advancing the reduction of memory cell size in this method, the potential VH in the surface of the substrate does not match with the formula (1), and it is affected by an influence of a potential of the adjacent channel.

There are four cases of FIGS. 8A, 8B, 9A, and 9B in the potential of the adjacent channel. And, in a case that both adjacent channels of the cell become the programming memory cell, the potential of the cell in the surface of the substrate (programming-prevent voltage) VH is decreased, so that the miss-programming occurs to the unselected memory cell USMC.

Note that, in the erasing, a voltage of about −20 V is applied to all of word lines which are inserted between the select transistor ST-Tr1 and the select transistor ST-Tr2 as shown in FIG. 6, so that electron is ejected from the floating gate 5 to the substrate via the gate insulator (tunnel insulator) 4 by Fowler-Nordheim tunnel current.

Accordingly, one object of the present invention is to provide a technique in which a reduction of the programming-prevent voltage is suppressed so that the miss-programming to the unselected memory cell is prevented in the nonvolatile semiconductor memory device.

The above and other objects and novel characteristics of the present invention will be apparent from the description of this specification and the accompanying drawings.

The typical ones of the inventions disclosed in the present application will be briefly described as follows.

That is, a nonvolatile semiconductor memory device according to the typical one is a nonvolatile semiconductor memory device which is electrically capable of programming/erasing. The nonvolatile semiconductor memory device has at least 3 or more memory cell columns in which a plurality of memory cells are connected in series, and these memory cell columns are adjacent to each other via a shallow trench isolation therebetween. And, the programming operation is performed individually to each of these memory cell columns.

Also, a nonvolatile semiconductor memory device according to another typical one is similarly a nonvolatile semiconductor memory device which is electrically capable of programming/erasing. The nonvolatile semiconductor memory device has at least 4 or more memory cell columns in which a plurality of memory cells are connected in series, and these memory cell columns are adjacent to each other via a shallow trench isolation therebetween. And, these memory cell columns are divided into groups having each 2 or more cell column which are adjacent to each other, and the programming operation is performed individually to each of these groups.

The effects obtained by typical aspects of the present invention will be briefly described below.

(1) It can suppress a word disturbance which increases as a width of a shallow isolation trench is narrower by scaling down of a pitch of a bit line.

(2) It can improve reliability of a nonvolatile semiconductor memory device.

### BRIEF DESCRIPTIONS OF THE DRAWINGS

FIG. 1 is a planer diagram showing one part of a memory cell array of a NAND-type flash memory;

FIG. 2 is a cross section diagram on A-A line in FIG. 1;

FIG. 3A is a cross section diagram on B-B line in FIG. 1;

FIG. 3B is a cross section diagram on C-C line in FIG. 1;

FIG. 4 is a schematic diagram of a circuit diagram of the memory cell array of the NAND-type flash memory;

FIG. 5 is a schematic diagram of a circuit diagram of the memory cell array of the NAND-type flash memory;

FIG. 6 is a schematic diagram of a circuit diagram of the memory cell array of the NAND-type flash memory;

FIG. 7A is a diagram showing an example of a voltage condition in a programming of the memory cell array of the NAND-type flash memory and shows a case that the programming is performed to the memory cell under a selected word line;

FIG. 7B is a diagram showing an example of a voltage condition in the programming of the memory cell array of the NAND-type flash memory and shows a case that the programming is not performed to the memory cell under the selected word line;

FIG. 8A is a diagram showing a surface of a silicon substrate in a case that the programming is not performed to the unselected memory cell USMC (the case of FIG. 7B), a surface of a silicon substrate under the memory cell which is adjacent in the floating gate and the word line direction, and a relation of the capacitive coupling to the silicon substrate, and shows the voltage condition in a case that the programming is performed to the memory cell which is adjacent to the unselected memory cell in the word line direction;

FIG. 8B is a diagram showing a surface of a silicon substrate in a case that the programming is not performed to the unselected memory cell USMC (the case of FIG. 7B), a surface of a silicon substrate under the memory cell which is adjacent in the floating gate and the word line direction, and a relation of the capacitive coupling to the silicon substrate, and shows the voltage condition in a case that the programming is not performed to the memory cell which is adjacent to the unselected memory cell in the word line direction;

FIG. 9A is a diagram showing a surface of a silicon substrate in a case that the programming is not performed to the unselected memory cell USMC (the case of FIG. 7B), a surface of a silicon substrate under the memory cell which is adjacent in the floating gate and the word line direction, and a relation of the capacitive coupling to the silicon substrate, and shows the voltage condition in a case that the programming is performed to the memory cell (right side) which is adjacent to the unselected memory cell in the word line direction;

FIG. 9B is a diagram showing a surface of a silicon substrate in a case that the programming is not performed to the unselected memory cell USMC (the case of FIG. 7B), a surface of a silicon substrate under the memory cell which is adjacent in the floating gate and the word line direction, and a relation of the capacitive coupling to the silicon substrate, and shows the voltage condition in a case that the programming is performed to the memory cell (left side) which is adjacent to the unselected memory cell in the word line direction;

FIG. 10 is a diagram showing an example of voltage application timing in the programming to B page of FIG. 5;

FIG. 11 is a diagram showing a part of configuration of a memory cell array in a nonvolatile semiconductor memory device according to a first embodiment of the present invention, and shows an example of a voltage condition in a programming to A page;

FIG. 12 is a diagram showing an example of voltage application timing in the programming to A page in the nonvolatile semiconductor memory device according to the first embodiment of the present invention;

FIG. 13 is a diagram showing an effect to improve a word disturbance in the nonvolatile semiconductor memory device according to the first embodiment of the present invention;

FIG. 14 is a diagram showing a part of configuration of a memory cell array in a nonvolatile semiconductor memory device according to a second embodiment of the present invention, and shows an example of a voltage condition in a programming to A page;

FIG. 15 is a diagram showing an example of a programming sequence in a nonvolatile semiconductor memory device according to a third embodiment of the present invention;

FIG. 16 is a diagram showing a part of configuration of a memory cell array in a nonvolatile semiconductor memory device according to a fourth embodiment of the present invention, and shows an example of a voltage condition in a programming to A page;

FIG. 17 is a diagram showing an example of voltage application timing in a programming to A page in the nonvolatile semiconductor memory device according to the fourth embodiment of the present invention;

FIG. 18 is a diagram showing an example of voltage application timing in a programming to A page in the nonvolatile semiconductor memory device according to the fourth embodiment of the present invention;

FIG. 19 is a diagram showing an example of a programming sequence in a nonvolatile semiconductor memory device according to a fifth embodiment of the present invention;

FIG. 20 is a diagram showing an example of a voltage condition in a programming to A page in a nonvolatile semiconductor memory device according to a sixth embodiment of the present invention; and

FIG. 21 is a diagram showing an example of voltage application timing in a programming to A page in the nonvolatile semiconductor memory device according to the sixth embodiment of the present invention.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted. Also, a symbol indicating a terminal name combines with a wire name and a signal name at the same time, and a symbol of power source combines with also a voltage value, unless otherwise stated.

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

### First Embodiment

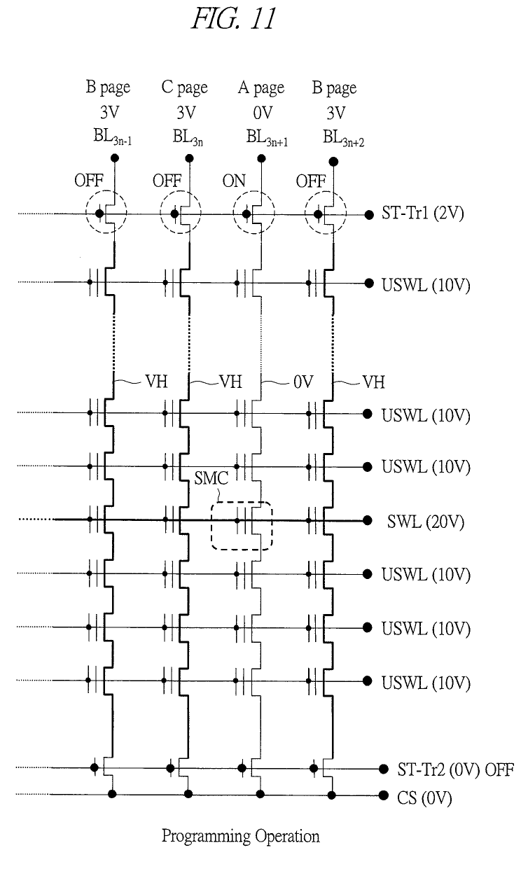

FIG. 11 is a diagram showing a part of configuration of a memory cell array in a nonvolatile semiconductor memory device according to a first embodiment of the present invention, and shows an example of a voltage condition in the programming to A page.

A nonvolatile semiconductor memory device according to a first embodiment of the present invention is a nonvolatile semiconductor memory device which is electrically capable of programming/erasing, and for example, it is a NAND-type flash memory which is capable of bulk erasing. The nonvolatile semiconductor memory device according to the first embodiment is formed by a general configuration including, for example, a memory cell array, a decoder, a sense latch circuit, data latch circuit, a main amplifier, an input data arithmetic circuit, an input/output buffer, a control signal input buffer, a data input/output control circuit, a ready/busy circuit, a system clock circuit, a command decoder, and others. And, the nonvolatile semiconductor memory device is formed on one semiconductor chip by a well-known semiconductor manufacturing technique.

In this flash memory, a control signal such as a chip-enable signal, a program-enable signal, a reset signal, a command data-enable signal, and an output-enable signal is inputted to the control signal input buffer via an external terminal, and a serial clock signal is inputted to the data input/output control circuit, and then, based on these signals, a command signal and a timing signal for an internal circuit control are generated. Also, a ready/busy signal is outputted from the ready/busy circuit via the external terminal.

In this flash memory, the memory cell array is configured with a plurality of memory cells MC which are arranged at an intersection of the word line WL and the bit line BL, and the memory cell array is divided into right and left, and top and bottom. An arbitrary memory cell MC which belongs to the memory cell array is selected by the decoder, and then, the programming/reading of data is performed to the selected memory cell MC via the sense latch circuit, the data latch circuit, the main amplifier, the input data arithmetic circuit, and the input/output buffer.

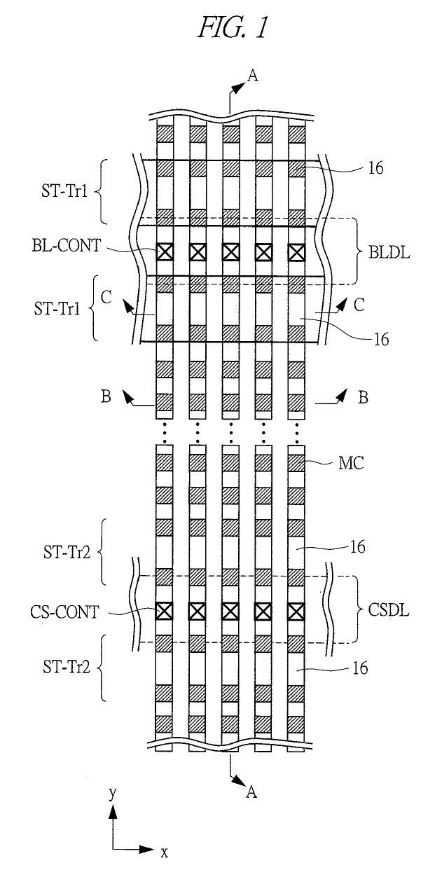

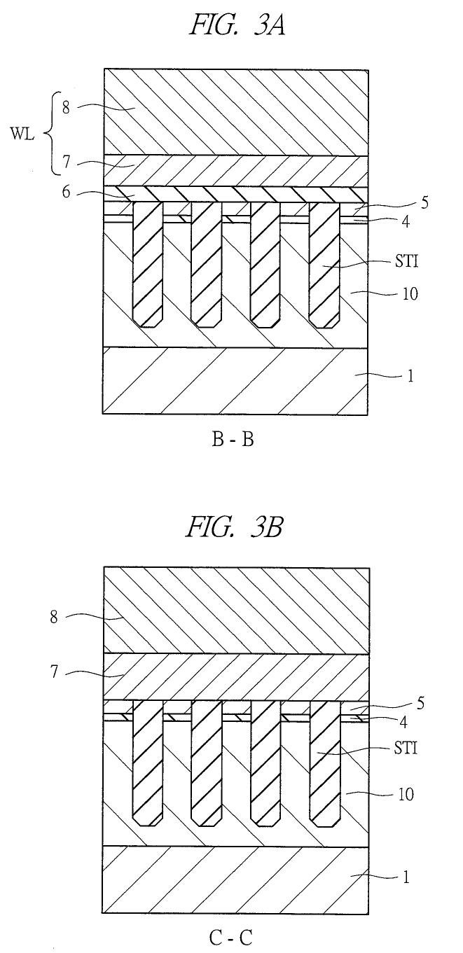

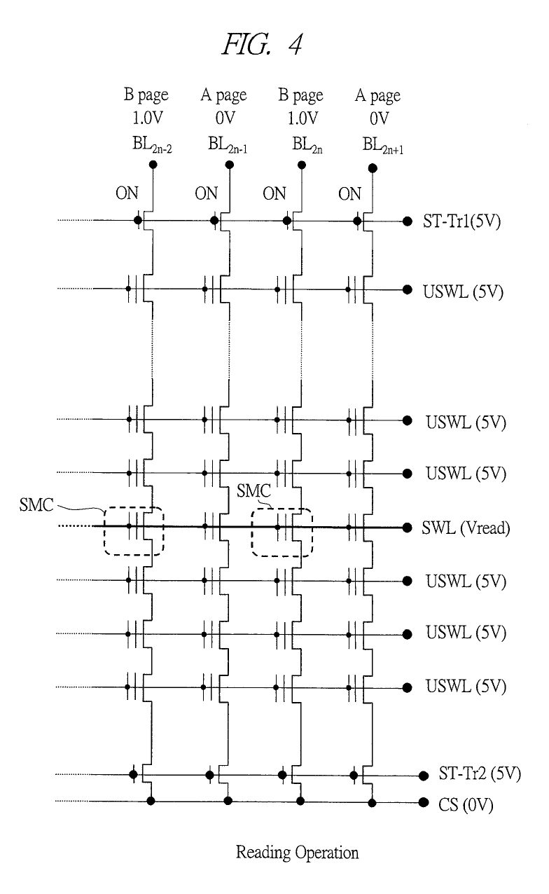

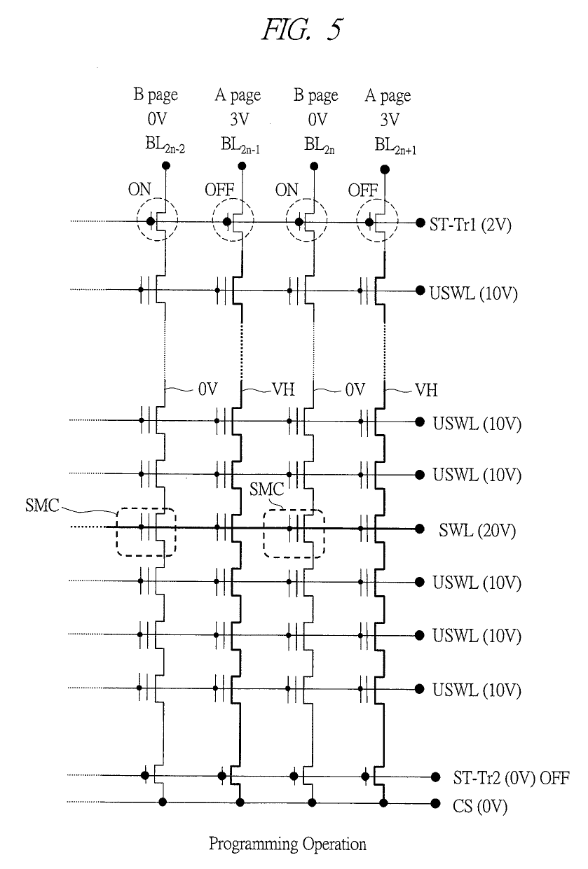

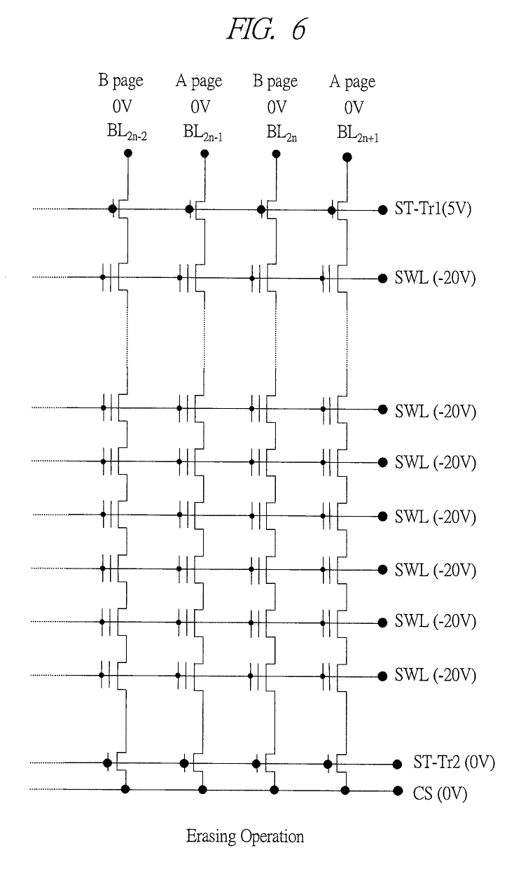

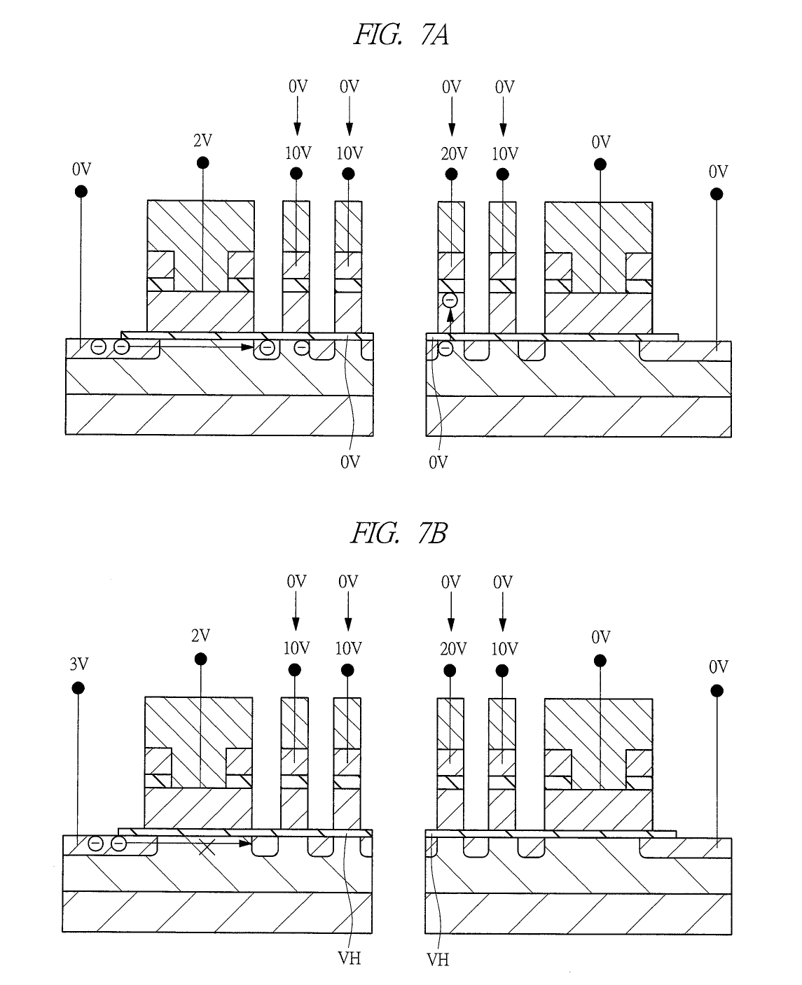

In the flash memory configured as described above, the memory cell array is configured, for example, as shown in FIG. 1 to FIG. 3, and FIG. 11. FIG. 11 is a diagram showing an example of a voltage condition in the programming to the memory cell.

As shown in FIG. 11, groups are made so as to divide the bit lines BL into each 2 bit lines, and each of the groups are, for example, an “A” page, a “B” page, and a “C” page. And, a voltage (for example, 20 V) is applied to the selected word line SWL, and the bit line voltage (for example, 3 V) is applied so as to programming-prevent in all of B and C pages when the programming is performed to A page. Also, when the programming is performed to B and C pages, all of the other pages are in a state to programming-prevent.

That is, the adjacent 3 bit lines are configured so as to belong to each of different pages, and the programming is performed individually to each of different pages.

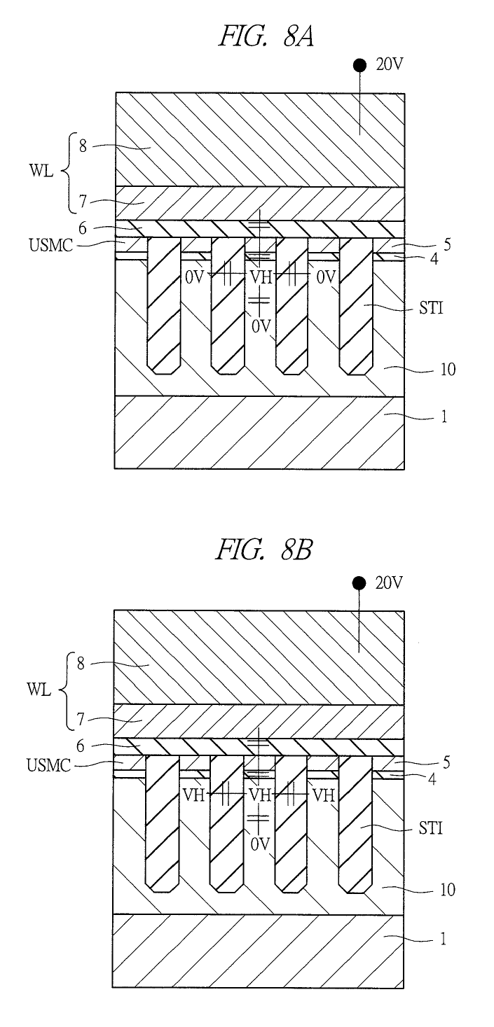

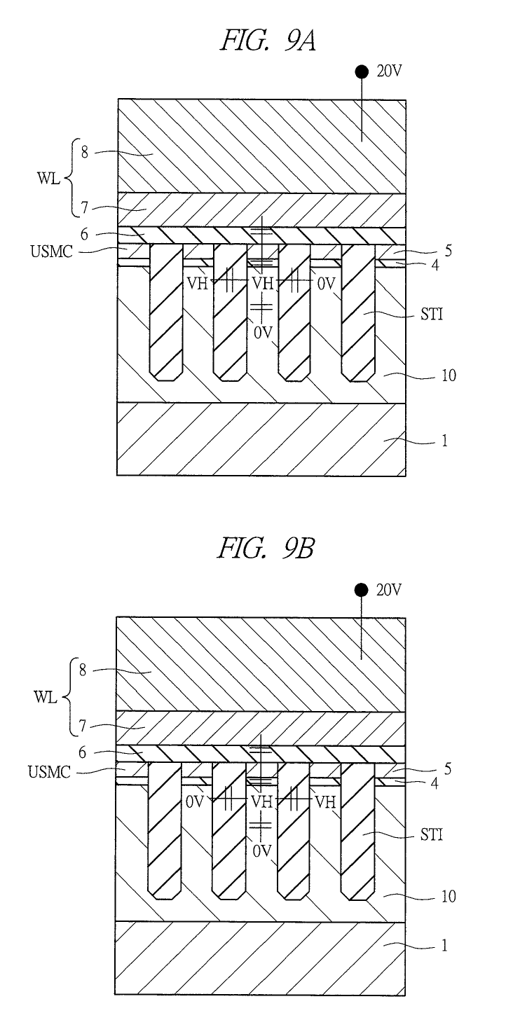

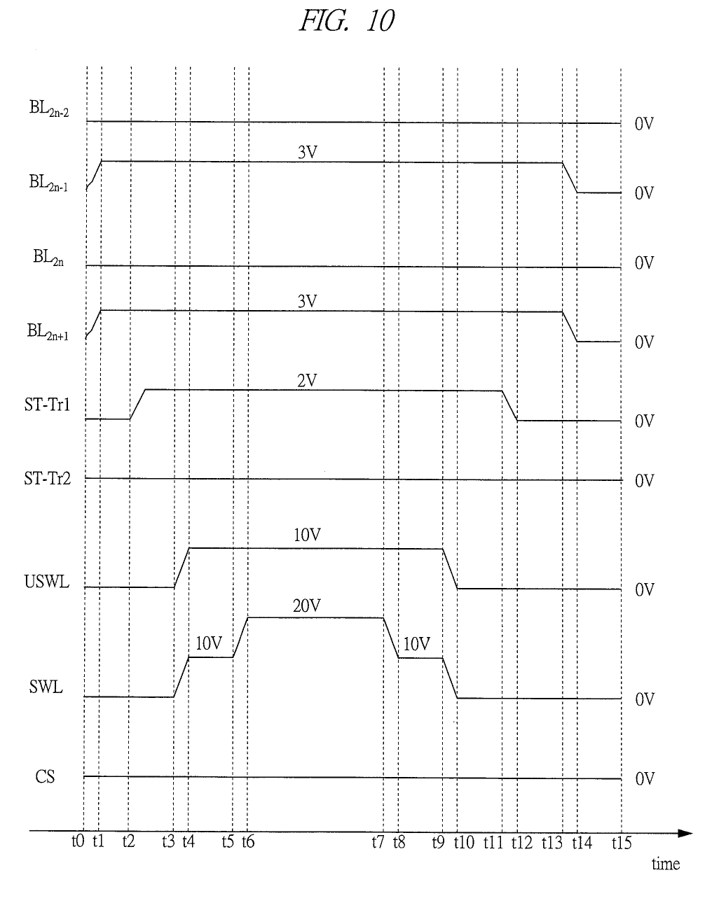

In such a manner, the programming-prevent voltage VH is surely provided on at least one side of both surfaces of the semiconductor substrate which are adjacent via the shallow trench isolation to the surface of the semiconductor substrate under the programming-prevented memory cell, so that it can avoid a state of FIG. 8A which is a problem in the programming to 2 pages, that is a state of a maximum reduction of the programming-prevent voltage VH due to the capacitive coupling between the surfaces of the semiconductor substrate, thereby largely reducing the miss-programming to the unselected memory cell USMC.

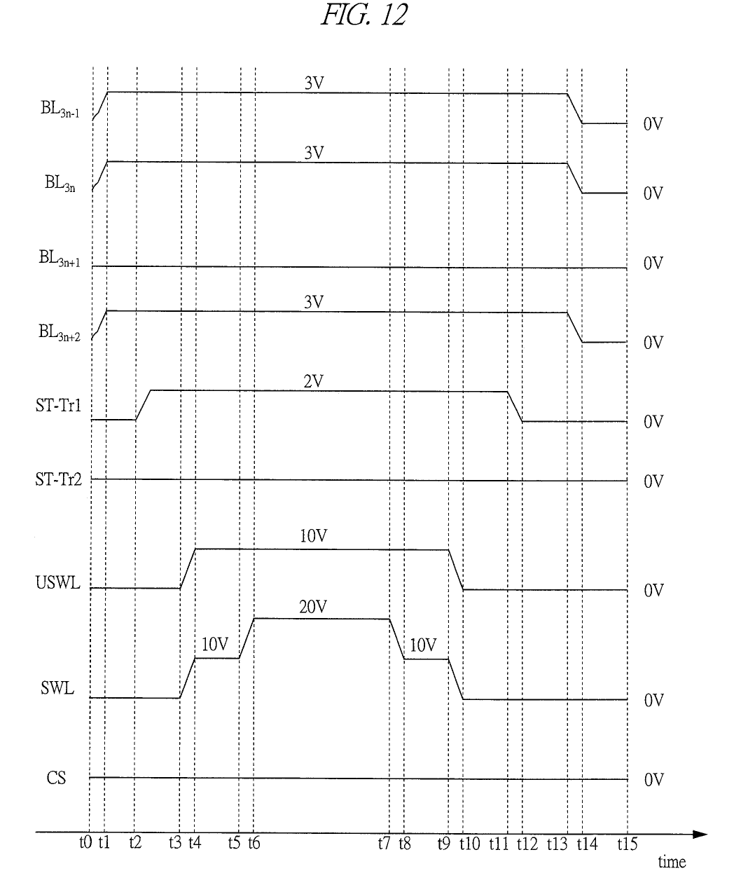

FIG. 12 is a timing diagram of the programming sequence, and more particularly, is an example of the programming to A page.

In the programming to the memory cell in A page, 0 V is applied to the bit line BL₃ₙ₊₁ in A page, and about 3 V is applied to the bit line BL₃ₙ₋₁ in B page and the bit line BL₃ₙ in C page (time t0 to t1). And, about 2 V is applied to the select transistor ST-Tr1 (time t2). The common source line CS, the select transistor ST-Tr2, and the p-type well are at 0 V. With this state, the potentials of the selected word line SWL and the unselected word line USWL are rapidly increased from 0 V to about 10 V (time t3 to t4, about several micro seconds or less). Accordingly, the potential of the floating gate under the unselected word line USWL increases, and by an influence of the potential, the potential of the surface of the semiconductor substrate under the memory cell also tends to increase.

Since the select transistor ST-Tr1 becomes OFF state when the bit line BL is set to about 3 V as B page and C page, the surface potential of the substrate under the memory cell increases to be VH. On the other hand, since the select transistor ST-Tr1 becomes ON state in the bit line BL of A page whose bit line potential is set to 0 V, electron is supplied from the bit line contact to the surface of the substrate under the memory cell, so that the potential of the surface of the substrate under the memory cell becomes 0 V.

Next, the potential of the selected word line SWL is increased from 10 V to about 20 V (time t5 to t6). At this time, in the bit line BL₃ₙ₊₁ in which the potential of the surface of the substrate is at 0 V, a large potential difference occurs between the floating gate and the surface of the substrate, so that electron is injected from the surface of the substrate to the floating gate of the selected memory cell SMC by the tunnel current, thereby causing the programming. On the other hand, in bit lines BL₃ₙ₋₁ and BL₃ₙ in which the potential of the surface of the substrate is at VH, the potential difference between the floating gate and the surface of the substrate is relaxed, thereby not causing the programming.

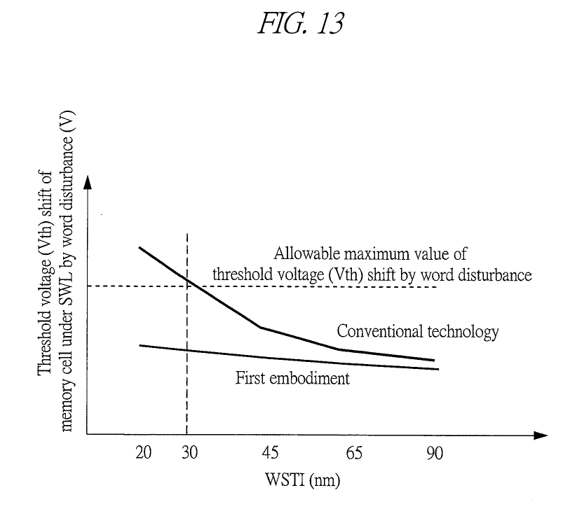

FIG. 13 is a diagram showing an effect to improve the word disturbance. In FIG. 13, a horizontal axis shows “WSTI” (Width of Trench Isolation), that is a width of the shallow trench isolation STI, and a vertical axis shows a threshold voltage (Vth) shift of a memory cell under the selected word line SWL by word disturbance (V).

As shown in FIG. 13, in the conventional technology, the threshold voltage shift by word disturbance extremely increases when the width of the shallow trench isolation STI is narrower, so that a required specification is not met when the width of the shallow trench isolation STI becomes 30 nm or less. However, in the first embodiment, the threshold voltage shift by word disturbance slightly increases even when the width of the shallow trench isolation STI is narrower, so that the required specification is sufficiently met even when the reduction of memory cell size is advanced. Therefore, according to the nonvolatile semiconductor memory device of the first embodiment, the miss-programming to the unselected memory cell USMC can be largely reduced compared to the conventional technology.

### Second Embodiment

While the programming is performed in dividing the cell under the selected word line SWL into 3 pages in the first embodiment, the programming can be also performed in dividing the cell under the selected word line SWL into 4 or more pages.

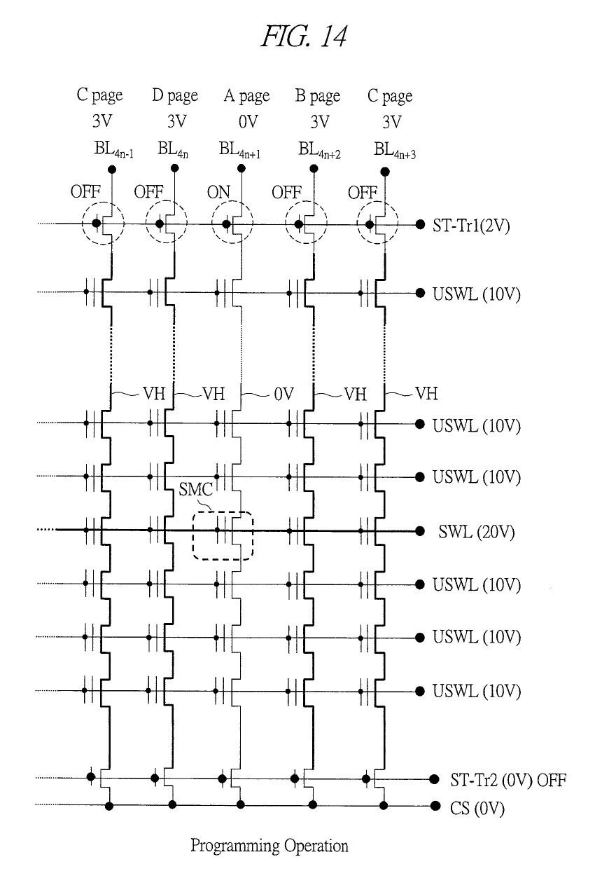

FIG. 14 is an example showing a voltage condition in a programming in a nonvolatile semiconductor memory device according to a second embodiment of the present invention.

As shown in FIG. 14, groups are made so as to divide the bit line BL into each 3 bit lines, and each of the groups is an A page, a B page, a C page, and a D page. And, a voltage (for example, 20 V) is applied to the selected word line SWL, and the bit line voltage (for example, 3 V) is applied so as to programming-prevent in all of B, C, and D pages when the programming is performed to A page. In such a manner, the programming-prevent voltage VH is surely provided on at least one side of both surfaces of the semiconductor substrate which are adjacent via the shallow trench isolation to the surface of the semiconductor substrate under the programming-prevented memory cell, so that it can avoid a state of FIG. 8A which is a problem in the programming to 2 pages, that is a state of a maximum reduction of the programming-prevent voltage VH due to the capacitive coupling between the surfaces of the semiconductor substrate, thereby largely reducing the miss-programming to the unselected memory cell USMC.

Therefore, according to the nonvolatile semiconductor memory device of the second embodiment, there is the effect to reduce the miss-programming to the unselected memory cell USMC similar to the first embodiment described above.

### Third Embodiment

In a third embodiment, such an operation is performed that, the programming to A, B, and C pages are gradually performed when the programming is performed in dividing the cell under the selected word line SWL into the 3 pages in the first embodiment and then the programming is ended at a stage that threshold voltages of all of memory cells in all of A, B, and C pages eventually reach a target threshold voltage.

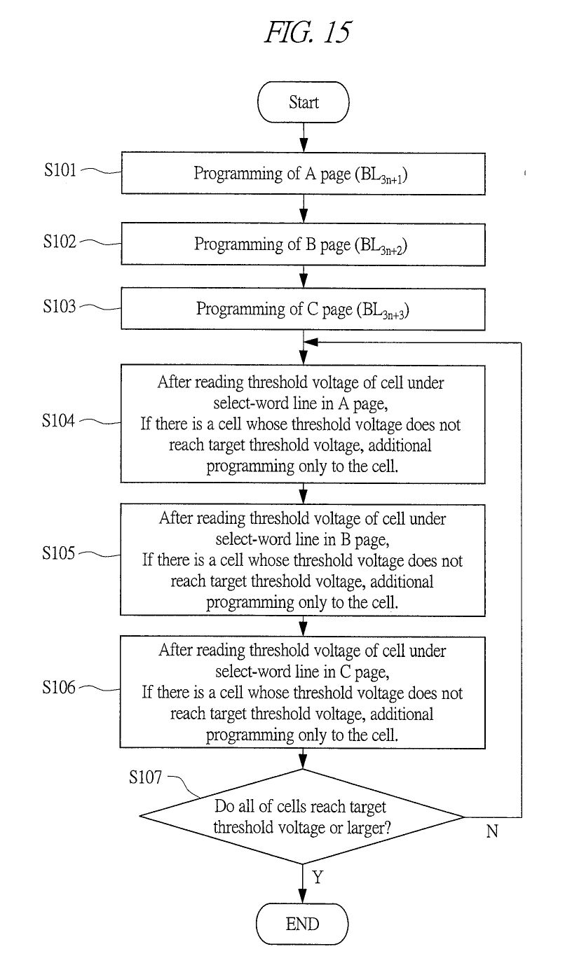

FIG. 15 is a flow chart showing a programming sequence in a nonvolatile semiconductor memory device according to a third embodiment of the present invention.

The programming in the nonvolatile semiconductor memory device according to the third embodiment of the present invention is executed by the following sequence.

First, the programming is performed to A page (BL₃ₙ₊₁) in a step S101. Next, the programming is performed to B page (BL₃ₙ₊₂) in a step S102. Next, the programming is performed to C page (BL₃ₙ₊₃) in a step S103.

Next, in a step S104, the threshold voltage of the memory cell SMC under the selected word line SWL in A page is read, and if there is a memory cell whose threshold voltage does not reach the target threshold voltage, an additional-programming is performed to only the memory cell. Next, in a step S105, the threshold voltage of the memory cell SMC under the selected word line SWL in B page is read, and if there is a memory cell whose threshold voltage does not reach the target threshold voltage, the additional-programming is performed to only the memory cell. Next, in a step S106, the threshold voltage of the memory cell SMC under the selected word line SWL in C page is read, and if there is a memory cell whose threshold voltage does not reach the target threshold voltage, the additional-programming is performed to only the memory cell.

And, in a step S107, the threshold voltages of all of the memory cells are read, and if threshold voltages of all of the memory cells reach the target threshold voltage, the programming is ended. If there is any one of memory cells whose threshold voltage does not reach the target threshold voltage, the operation goes back to the step S104, and then the steps S104 to S107 are executed.

By using such a programming method, after the programming is ended when a threshold voltage of any one focusing cell of memory cells is over the target threshold voltage, a fluctuation of the threshold voltage of the memory cell which is adjacent to the focusing cell in the word line direction can be reduced, thereby also capable of obtaining the effect to reduce the threshold voltage shift due to the capacitive coupling between the adjacent floating gates.

### Fourth Embodiment

While the programming is performed in dividing the cell under the selected word line into 3 or more pages in the first and second embodiments, the same effect can be obtained even in 2 pages depending on how groups are made by dividing for pages.

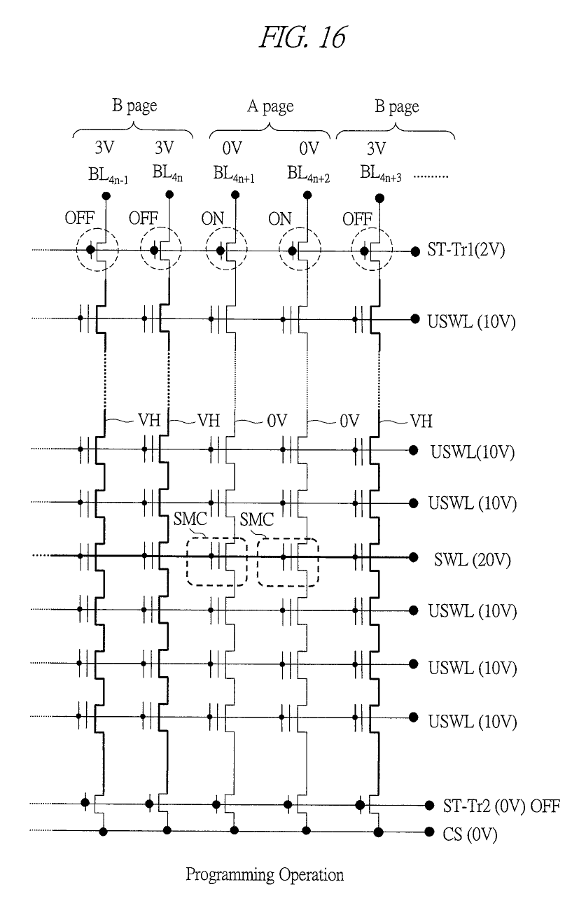

FIG. 16 is an example showing a voltage condition in a programming in a nonvolatile semiconductor memory device according to a fourth embodiment of the present invention. FIG. 16 shows the example of the voltage condition in the programming to A page.

As shown in FIG. 16, groups are made so as to divide the bit line BL into 2 continuing bit lines, and each of the groups is an A page, and a B page. And, a voltage (for example, 20 V) is applied to the selected word line SWL, and the bit line voltage (for example, 3 V) is applied so as to programming-prevent in all of B pages when the programming is performed to A page. In such a manner, the programming-prevent voltage VH is surely provided on at least one side of both surfaces of the semiconductor substrate which are adjacent via the shallow trench isolation to the surface of the semiconductor substrate under the programming-prevented cell, so that it can avoid a state of FIG. 8A which is a problem in the conventional programming to 2 pages, that is a state of a maximum reduction of the programming-prevent voltage VH due to the capacitive coupling between the surfaces of the semiconductor substrate, thereby largely reducing the miss-programming to the unselected memory cell USMC.

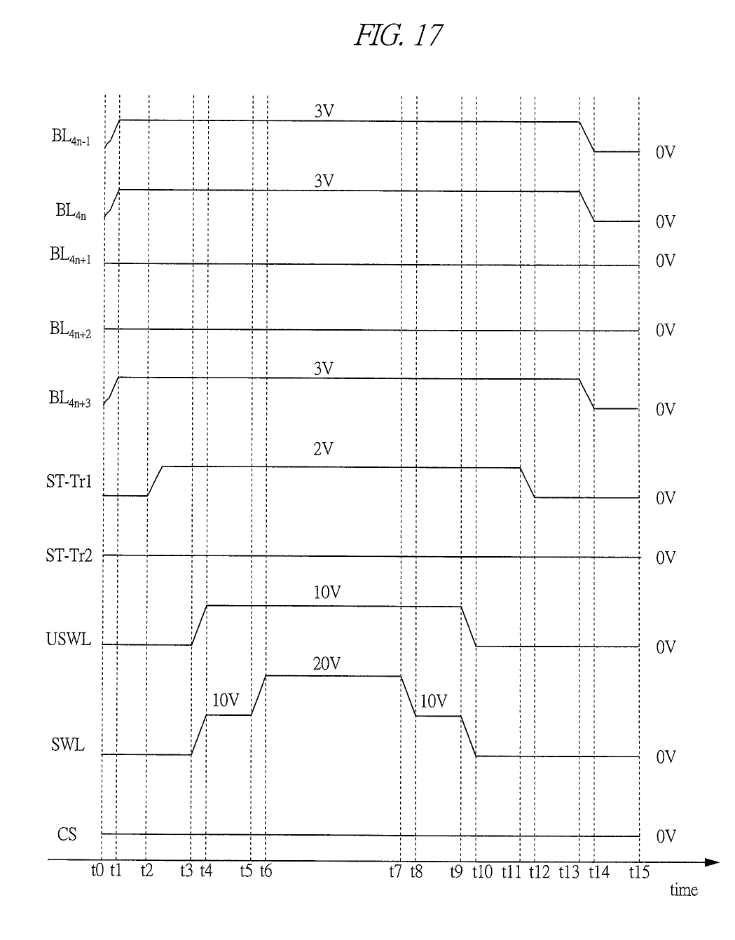

FIG. 17 is a timing diagram of a programming sequence, and more particularly, is an example in a programming to A page.

In the programming to the memory cell in A page, 0 V is applied to the bit lines BL₄ₙ₊₁ and BL₄ₙ₊₂ in A page, and about 3 V is applied to the bit lines BL₄ₙ₋₁, BL₄ₙ, and BL₄ₙ₊₃ in B page (time t0 to t1). And, about 2 V is applied to the select transistor ST-Tr1 (time t2). The common source line CS, the select transistor ST-Tr2, and the p-type well are at 0 V. With this state, the potentials of the selected word line SWL and the unselected word line USWL are rapidly increased from 0 V to about 10 V (time t3 to t4, about several micro seconds or less). Accordingly, a potential of the floating gate under the unselected word line USWL increases, and by an influence of the potential, a potential of the surface of the substrate under the memory cell also tends to increase.

Since the select transistor ST-Tr1 becomes OFF state when the bit line BL is set to about 3 V as B page, the surface potential of the substrate under the memory cell increases to be VH. On the other hand, since the select transistor ST-Tr1 becomes ON state in the bit line BL of A page whose bit line potential is set to 0 V, electron is supplied from the bit line contact side to the surface of the substrate under the memory cell, so that the potential of the surface of the substrate under the memory cell becomes 0 V.

Next, the potential of the selected word line SWL is increased from 10 V to about 20 V (time t5 to t6). At this time, in the bit lines BL₄ₙ₊₁ and BL₄ₙ₊₂ in which the potential of the surface of the substrate is at 0 V, a large potential difference occurs between the floating gate and the surface of the substrate, so that electron is injected from the surface of the substrate to the floating gate of the selected memory cell SMC by the tunnel current, thereby causing the programming. On the other hand, in bit lines BL₄ₙ₋₁, BL₄ₙ, and BL₄ₙ₊₃ in which the potential of the surface of the substrate is at VH, the potential difference between the floating gate and the surface of the substrate is relaxed, thereby not causing the programming.

Also in the fourth embodiment, the effect to reduce the miss-programming to the unselected memory cell USMC has been found similar to the first embodiment.

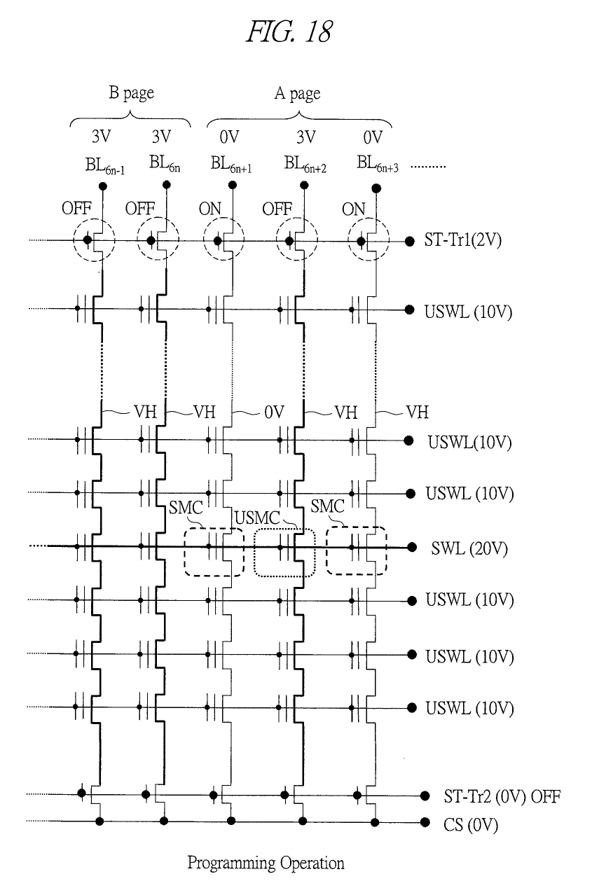

FIG. 18 is a diagram showing an example of voltage application timing in a programming to A page in the nonvolatile semiconductor memory device according to the fourth embodiment of the present invention. FIG. 18 shows an example of a voltage condition in the programming to A page.

As shown in FIG. 18, a method in which 3 or more continuing bit lines are assigned to the same page can be also considered. Although the case of FIG. 18 has the effect to reduce the miss-programming compared to the conventional technology, the effect to reduce the miss-programming is reduced by half since the state of FIG. 8A might occur as shown in the bit line BL₆ₙ₊₂.

### Fifth Embodiment

In a fifth embodiment, such an operation is performed that, the programming to A and B pages is gradually performed when the programming is performed in dividing the memory cell under the selected word line SWL into 2 pages in the fourth embodiment (FIG. 16), and then the programming is ended at a stage that threshold voltages of all of memory cells in all of A and B pages eventually reach the target threshold voltage.

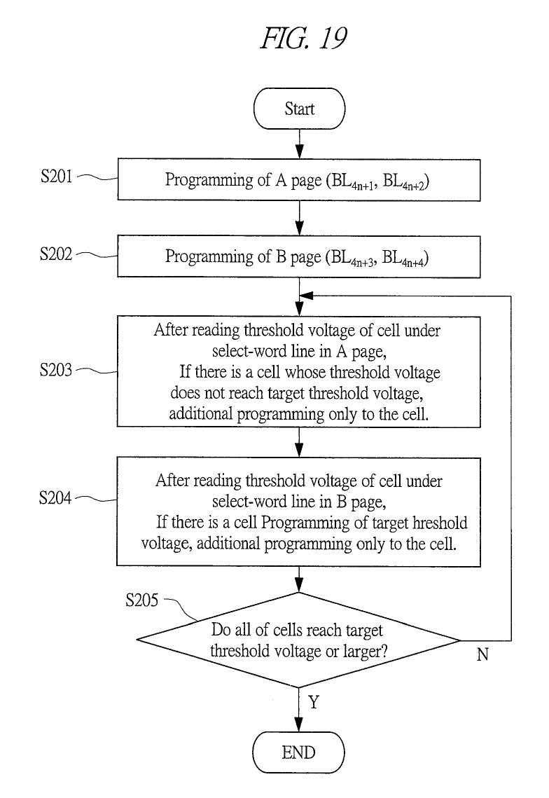

FIG. 19 is a flow chart showing a programming sequence in a nonvolatile semiconductor memory device according to the fifth embodiment of the present invention.

The programming in the nonvolatile semiconductor memory device according to the fifth embodiment of the present invention is executed by the following sequence. Note that a configuration of the memory cell array is same with the one shown in FIG. 16.

First, the programming is performed to A page (BL₄ₙ₊₁ and BL₄ₙ₊₂) in a step S201. Next, the programming is performed to B page (BL₄ₙ₊₃ and BL₄ₙ₊₄) in a step S202.

Next, in a step S203, the threshold voltage of the memory cell SMC under the selected word line SWL in A page is read, and if there is a memory cell whose threshold voltage does not reach the target threshold voltage, the additional-programming is performed to only the memory cell. Next, in a step S204, the threshold voltage of the memory cell SMC under the selected word line SWL in B page is read, and if there is a memory cell whose threshold voltage does not reach the target threshold voltage, the additional-programming is performed to only the memory cell.

And, in a step S205, the threshold voltages of all of the memory cells are read, and if threshold voltages of all of the memory cells reach the target threshold voltage, the programming is ended. If there is any one of memory cells whose threshold voltage does not reach the target threshold voltage, the operation goes back to the step S203, and then the steps S203 to S205 are executed.

By using such a programming method, after the programming is ended when a threshold voltage of any one focusing cell of memory cells is over the target threshold voltage, a fluctuation of the threshold voltage of the cell which is adjacent to the focusing cell in the word line direction can be reduced, thereby also capable of obtaining the effect to reduce the threshold voltage shift due to the capacitive coupling between the adjacent floating gates.

### Sixth Embodiment

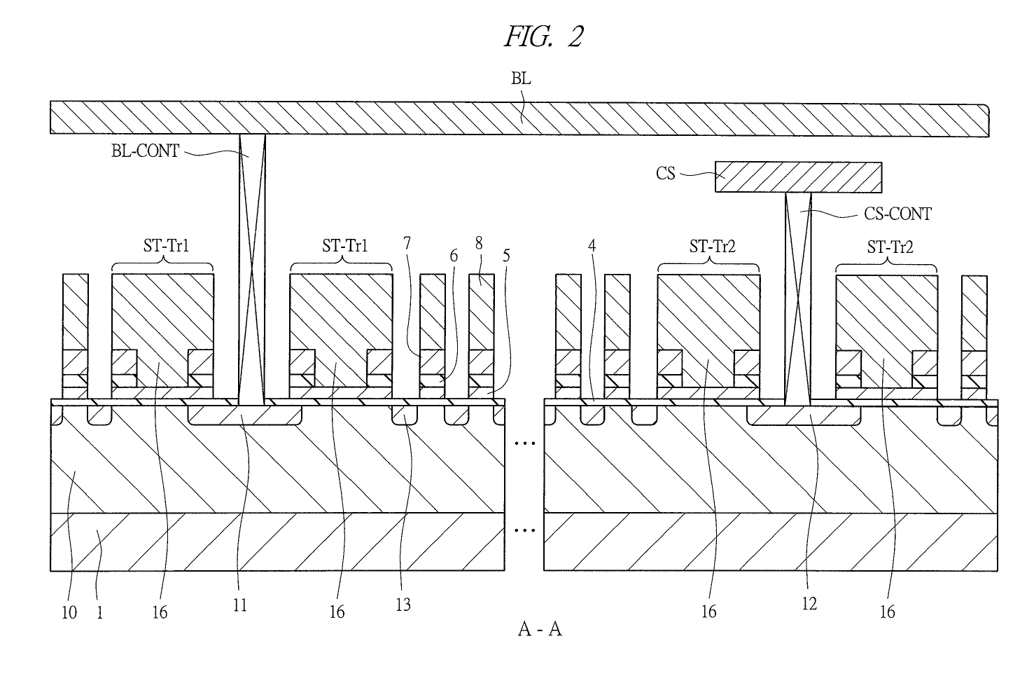

In the first to fifth embodiments, the bit line contact BL-CONT is provided in each series connection of the memory cell MC as shown in FIGS. 1 and 2. However, in a sixth embodiment, the bit line contact BL-CONT is provided as one in each two series connections of the memory cell MC. And, the select transistors ST-Tr1-1 and ST-Tr1-2 are provided by dividing the select transistor ST-Tr1 into two. Also in such a NAND-type flash memory, the operation to reduce the miss-programming can be also performed.

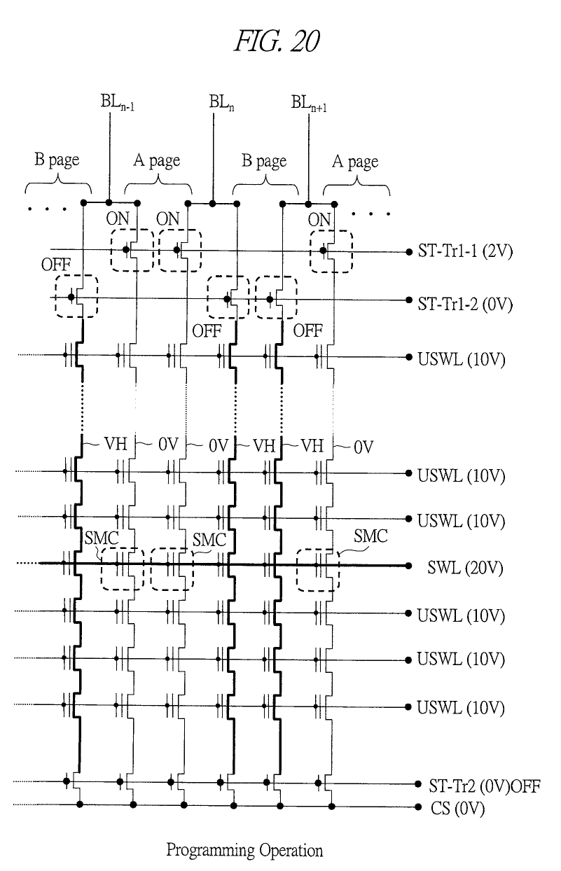

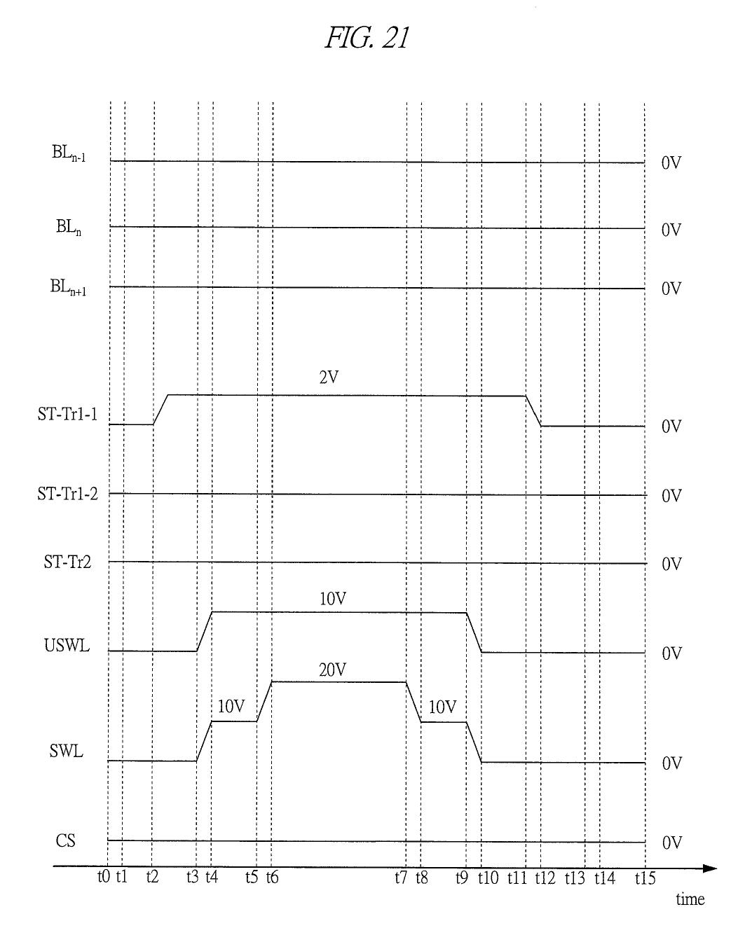

FIG. 20 is a diagram showing an example of a voltage condition in a programming to A page in a nonvolatile semiconductor memory device according to the sixth embodiment of the present invention. FIG. 21 is a timing diagram of the programming sequence, and more particularly, is an example in the programming to A page.

As shown in FIG. 20, transistors are added so that the select transistor ST-Tr1 becomes the select transistors ST-Tr1-1 and ST-Tr1-2.

In the programming to the memory cell in A page, about 2 V is applied to the select transistor ST-Tr1-1, and 0 V is applied to the select transistor ST-Tr1-2. 0 V is applied to the bit line BL which performs the programming to the memory cell in A page, and about 3 V is applied to the bit line BL which does not perform the programming. The common source line CS, the select transistor ST-Tr2, and the p-type well are at 0 V. With this state, the potentials of the selected word line SWL and the unselected word line USWL are rapidly increased from 0 V to about 10 V (about several micro seconds or less). Accordingly, a potential of the floating gate under the unselected word line USWL increases, and by an influence of the potential, a potential of the surface of the semiconductor substrate under the memory cell also tends to increase.

Since the select transistor ST-Tr1 becomes OFF state when the bit lines BL is set to about 3 V, the surface potential of the substrate under the memory cell increases to be VH. On the other hand, since the select transistor ST-Tr1 becomes ON state in the bit line BL whose bit line potential is set to 0 V, electron is supplied from the bit line contact side to the surface of the substrate under the memory cell, so that the potential of the surface of the substrate under the memory cell becomes 0 V.

Next, the potential of the selected word line SWL is increased from 10 V to about 20 V. At this time, in the bit line in which the potential of the surface of the substrate is at 0 V, a large potential difference occurs between the floating gate and the surface of the substrate, so that electron is injected from the surface of the substrate to the floating gate by the tunnel current, thereby causing the programming. On the other hand, in the bit line BL in which the potential of the surface of the substrate is at VH, the potential difference between the floating gate and the surface of the substrate is relaxed, thereby not causing the programming.

Also, since the select transistor ST-Tr1-2 is in OFF state at 0 V in this operation, all of the surfaces of the semiconductor substrate under the memory cells in B page are at the programming-prevent voltage VH, and therefore, B page is in state of the programming-prevent.

In such a manner, the programming-prevent voltage VH is surely provided on at least one side of both surfaces of the semiconductor substrate which are adjacent via the shallow trench isolation to the surface of the semiconductor substrate under the programming-prevented cell. Therefore, it can avoid a state of FIG. 8A which is a problem in the conventional programming to 2 pages, that is a state of a maximum reduction of the programming-prevent voltage VH due to the capacitive coupling between the surfaces of the semiconductor substrate. Thereby, the miss-programming to the unselected memory cell USMC can be largely reduced.

Therefore, also in the sixth embodiment, there is the effect to reduce the miss-programming to the unselected memory cell USMC similar to the first embodiment.

In the foregoing, the invention made by the inventors of the present invention has been concretely described based on the embodiments. However, it is needless to say that the present invention is not limited to the foregoing embodiments and various modifications and alterations can be made within the scope of the present invention. Also, the first to sixth embodiments described above can be properly combined with each other.

The present invention prefers to use for a flash memory, and more particularly, for a memory device for a personal digital assistant such as a mobile personal computer and a digital still camera.

What is claimed is:

1. A nonvolatile semiconductor memory device which is electrically capable of programming/erasing, comprising:
a first memory cell column connecting in series to a plurality of first memory cells;
a second memory cell column connecting in series to a plurality of second memory cells; and
a third memory cell column connecting in series to a plurality of third memory cells, wherein
the second memory cell column is adjacent to the first memory cell column via a first shallow trench isolation,
the third memory cell column is adjacent to the second memory cell column via a second shallow trench isolation, and
a programming operation is individually performed to each of the first, second, and third memory cell columns.

2. The nonvolatile semiconductor memory device according to claim 1, wherein
the programming operation comprises:
a first step of performing a programming to the first memory cell column;
a second step of performing the programming to the second memory cell column;
a third step of performing the programming to o the third memory cell column;
a fourth step of performing an additional-programming in a case that, after reading a threshold voltage of one of the first memory cells which belong to the first memory cell column, the read threshold voltage does not reach a target threshold voltage;
a fifth step of performing an additional-programming in a case that, after reading a threshold voltage of one of the second memory cells which belong to the second memory cell column, the read threshold voltage does not reach the target threshold voltage; and
a sixth step of performing an additional-programming in a case that, after reading a threshold voltage of one of the third memory cells which belong to the third memory cell column, the read threshold voltage does not reach the target threshold voltage, and wherein
the fourth to sixth steps are repeatedly performed until the threshold voltages of all the memory cells in each of the memory cell columns reach the target threshold voltage.

3. A nonvolatile semiconductor memory device which is electrically capable of programming/erasing, comprising:
a first memory cell column connecting in series to a plurality of first memory cells;
a second memory cell column connecting in series to a plurality of second memory cells;
a third memory cell column connecting in series to a plurality of third memory cells; and
a fourth memory cell column connecting in series to a plurality of fourth memory cells, wherein
the second memory cell column is adjacent to the first memory cell column via a first shallow trench isolation,
the third memory cell column is adjacent to the second memory cell column via a second first shallow trench isolation,
the fourth memory cell column is adjacent to the third memory cell column via a third first shallow trench isolation,
a programming operation is simultaneously performed to each of the first and second memory cell columns,
a programming operation is simultaneously performed to each of the third and fourth memory cell columns, and
a programming operation is individually performed to each of the first and third memory cell columns.

4. The nonvolatile semiconductor memory device according to claim 3, wherein
the programming operation comprises:
a first step of performing the programming to the first and second memory cell columns;
a second step of performing the programming to the third and fourth memory cell columns;
a third step of performing an additional-programming in a case that, after reading a threshold voltage of one of the first and second memory cells which belong to each of the first and second memory cell columns, the read threshold voltage does not reach a target threshold voltage; and
a fourth step of performing an additional-programming in a case that, after reading a threshold voltage of one of the third and fourth memory cells which belong to each of the third and fourth memory cell columns, the read threshold voltage does not reach the target threshold voltage, and wherein
the third to fourth steps are repeatedly performed until the threshold voltages of all the memory cells in each of the memory cell columns reach the target threshold voltage.

5. The nonvolatile semiconductor memory device according to claim 3, wherein
the second and third memory cell columns are connected to a same bit line via two different select transistors.

6. A nonvolatile semiconductor memory device which is electrically capable of programming/erasing, comprising:
a first memory cell column connecting in series to a plurality of first memory cells;
a second memory cell column connecting in series to a plurality of second memory cells;
a third memory cell column connecting in series to a plurality of third memory cells; and
a fourth memory cell column connecting in series to a plurality of fourth memory cells, wherein
the second memory cell column is adjacent to the first memory cell column via a first shallow trench isolation,
the third memory cell column is adjacent to the second memory cell column via a second shallow trench isolation,
the fourth memory cell column is adjacent to the third memory cell column via a third shallow trench isolation, and
a programming operation is individually performed to each of the first, second, third, and fourth memory cell columns.
